(19) United States
(12) Patent Application Publication
(10) Pub. No.: US 2005/0111176 A1
(43) Pub. Date: May 26, 2005

(54) Sidewall display system

(76) Inventors: Shane D. Sorensen, Eugene, OR (US); Joel A. Wilson, Eugene, OR (US)

Correspondence Address: KOLISCH HARTWELL, P.C., 520 S.W. YAMHILL STREET, SUITE 200, PORTLAND, OR, 97204, US

(21) Appl. No.: 10/956,732

(22) Filed: Oct. 1, 2004

Related U.S. Application Data
(60) Provisional application No. 60/508,435, filed on Oct. 3, 2003.

(51) Int. Cl. G06F 1/16; H05K 5/00; H05K 7/00; G09G 5/00

(52) U.S. Cl. 361/682

(57) ABSTRACT

A display system including a frame assembly, which includes a mounting plate, and a video display moveably connected to the frame assembly, wherein the video display is selectively moveable throughout a range of positions. The display system also includes at least a first curvature accommodating bar extending laterally along a backside of the mounting plate, wherein the first curvature accommodating bar is pivotably connected to the mounting plate. The display system also includes a first adjustable spacer configured to set the relative degree of pivot between the first curvature accommodating bar and the mounting plate. According to another aspect of some embodiments of the invention, the video display may be selectively configured to open from either the left side or the right side of the display system.

### CROSS-REFERENCES

This application claims the benefit of U.S. Provisional Application No. 60/508,435, filed Oct. 3, 2003, which is hereby incorporated herein by reference.

### BACKGROUND

Audio-visual media is becoming increasingly popular in a variety of settings. In particular, personal video display systems can now be found in vehicles such as cars, trucks, and vans. Such video display systems can be used to display navigational information, vehicle control information, entertainment content, or virtually any other desired audio-visual media.

As audio-visual media has become more popular in vehicles, various display systems have been designed to position such displays for convenient viewing. For example, some displays have been designed for location in the back of a front passenger seat, some displays have been designed to be suspended from a vehicle ceiling, some displays have been designed to be located in the front or rear console of a vehicle, and some displays have been designed to emerge from the armrest of a vehicle seat.

### BRIEF DESCRIPTION OF THE DRAWINGS

FIG. 1 is a side view showing a display system mounted to an inwardly curving sidewall.

FIG. 2 is a top view of the display system of FIG. 1, showing a positioning assembly moving a video display into a deployed position.

FIG. 3 is a top view of the display system of FIG. 1, showing the video display swivel about a substantially vertical axis.

FIG. 4 is a side view of the display system of FIG. 1, showing the video display tilt about a substantially horizontal axis.

FIG. 5 is a close up of a curvature accommodating device of the display system of FIG. 1.

FIG. 6 is a front view of the display system of FIG. 1, showing the video display facing outward.

FIG. 7 is a front view of the display system of FIG. 1, showing the video display facing inward and showing the positioning assembly adapted to open from the left side of a frame assembly.

### DETAILED DESCRIPTION

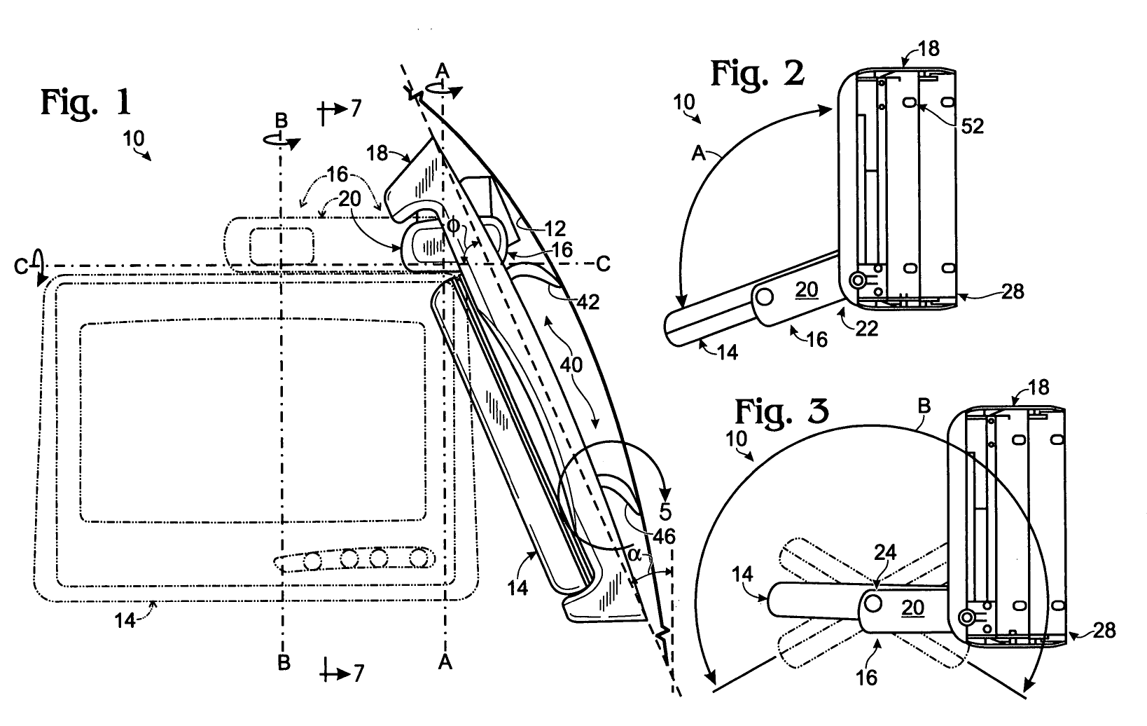

FIG. 1 schematically shows a side-view of a display system 10 mounted to an inwardly curving sidewall 12, such as an inwardly curving sidewall found in an airplane or other vehicle. Display system 10 includes a video display 14 for presenting audio-visual content, a positioning assembly 16 for moving the video display throughout a range of positions, and a frame assembly 18 for mounting the display system to the sidewall.

Video display 14 can include a liquid crystal display, plasma display, or virtually any other display with a relatively shallow form factor. The video display can be sized and shaped according to a desired use. As a nonlimiting example, the video display can include a screen having a 7 inch diagonal viewing area with a 16:9 aspect ratio and a 480×234 resolution. Of course, other screen sizes, shapes, and resolutions are within the scope of this disclosure.

Video display 14 can be positioned and secured in a stowed position in which the display is orientated substantially parallel to sidewall 12, as shown in solid lines in FIG. 1. When in the stowed position, the video display may be less exposed to potential damage and may be clear from obstructing the view of other items. For example, when mounted in an aircraft, the video display can be moved to a stowed position to help protect the video display during takeoff and landing. As explained below, display 14 can be positioned to face outward when in a stowed position, and the display can be used when in a stowed position.

Positioning assembly 16 can be configured to move the video display throughout a range of positions. In particular, the positioning assembly can move the video display into a deployed position, as shown in dashed lines in FIG. 1. Positioning assembly 16 can include one or more joints, latches, and support arms for moving the video display. In some embodiments, the positioning assembly can be configured to keep the video display substantially level throughout its full range of motion. As used herein, “level,” “horizontal,” and “vertical” refer to a perceived orientation relative to a viewer and not to an outside reference such as the earth. In the context of an airplane or other vehicle, “level” may be defined as being substantially parallel to the seat of a passenger viewing the video display. While a video display may tilt left and right relative to the earth as an airplane banks or rolls, it can remain “level” with reference to a passenger viewer that is also banking and rolling with the airplane.

When in a deployed position, the video display can be adjusted to have a desired orientation for convenient viewing. For example, in the illustrated embodiment, the positioning assembly includes an arm 20 that can pivot about a substantially vertical axis A-A. Furthermore, in the illustrated embodiment, the video display is connected to arm 20 so that the video display can swivel about a substantially vertical axis B-B and tilt about a substantially horizontal axis C-C. Therefore, the illustrated display system has three separate degrees of freedom that allow the video display to be positioned with a desired orientation. FIGS. 2-4 independently illustrate each degree of freedom.

FIG. 2 shows a top view of display system 10 in a deployed position. As indicated by arrow A, a positioning assembly 16 of the display system can be used to selectively move the video display from a stowed position to a deployed position by rotating arm 20 about axis A-A. An arm rotation joint 22 pivotably connects arm 20 to frame assembly 18 and is configured to permit rotation of arm 20 about axis A-A. In the illustrated embodiment, the orientation of arm 20 effectively controls the orientation of video display 14. When arm 20 is constrained to remain horizontal, the video display remains level. Accordingly, arm rotation joint 22 can be configured to hold arm 20 horizontal while the arm pivots. As a nonlimiting example, the arm rotation joint can be configured to pivot arm 20 throughout an arc of 120 degrees while holding the arm substantially horizontal.

As indicated by arrow B in FIG. 3, the positioning assembly can be configured to allow video display 14 to swivel about axis B-B. A display rotation joint 24 pivotably connects video display 14 to arm 20 and is configured to permit rotation of the video display about axis B-B. The ability to swivel the screen about axis B-B can facilitate squaring the video display to achieve an improved viewing angle. In particular, the video display can be swiveled to accommodate viewers having a line-of-sight to the left or right of the display. The display rotation joint can be configured to maintain a level screen orientation throughout the entire range of motion as the display pivots about axis B-B, or in other words, the joint can prevent the display from rotating about an axis that is orthogonal to axis B-B and axis C-C. As a nonlimiting example, the joint can provide for 210 degrees of swivel. As such, the display can be swiveled to face forward or backward when in a deployed position. Similarly, as explained with reference to FIGS. 6 and 7, the display can be swiveled to face inward or outward when in a stowed position.

As indicated by arrow C in FIG. 4, the positioning assembly can be configured to allow video display 14 to tilt forward and/or backward about axis C-C. A display tilt joint 26 pivotably connects video display 14 to arm 20 and is configured to permit the video display to tilt about axis C-C. The ability to tilt the screen about axis C-C can facilitate squaring the video display to achieve an improved viewing angle. In particular, the video display can be tilted to accommodate viewers having a line-of-sight above or below the display. The display tilt joint can be configured to maintain a level screen orientation throughout the entire range of motion as the display tilts about axis C-C. As a nonlimiting example, the display tilt joint can provide for 60 degrees of tilt, or more precisely, 30 degrees of forward tilt and 30 degrees of backward tilt. In some embodiments, display rotation joint 24 and display tilt joint 26 can be integrated into a compound joint that permits rotation about axis B-B and axis C-C. Such a compound joint can be configured to keep the display level.

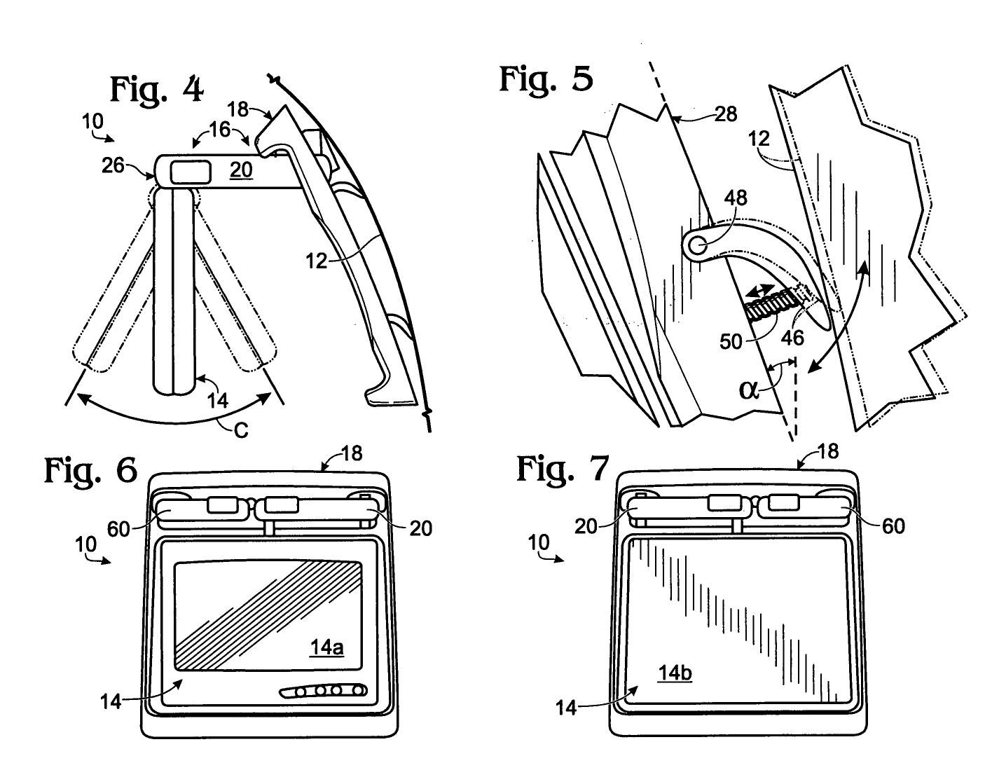

As shown in FIG. 1, display system 10 is mounted to an inwardly curving sidewall 12. In some embodiments, frame assembly 18 of the display system may include a substantially planar rear mounting plate 28, as shown in FIG. 5. The mounting plate may have a shape that does not closely correspond to the curvature of an inwardly curving sidewall. As used herein, a “plate” is not limited to a continuous solid expanse and may include two or more discrete portions that are spaced apart from one another. When a mounting plate does not closely correspond to the shape of a sidewall to which the plate is to be mounted, one or more curvature accommodating devices 40 can be used to improve the connection between the display system and the sidewall. In particular, a curvature accommodating device can effectively serve as a shim that spans a gap between a portion of the display system, such as a mounting plate, and the sidewall. FIG. 1 shows two pivoting bars 42 and 46, which can be selectively adjusted to span such a gap at two spaced-apart locations.

FIG. 5 shows a close-up view of curvature accommodating bar 46. The curvature accommodating bar is pivotably connected to mounting plate 28 at a joint 48. A curvature accommodating device may also include an adjustment mechanism to accommodate for different amounts of curvature and/or different positioning. In the illustrated embodiment, the curvature accommodating device includes an adjustment mechanism in the form of a set screw 50, which can be set to adjust the relative extension of the curvature accommodating bar away from mounting plate 28. For example, the bar can be set further away from the mounting plate, as shown in dashed lines, to accommodate a sidewall with a tighter radius of curvature.

Display system 10 can be fastened to sidewall 12 by a variety of different mechanisms. For example, a fastener such as a screw, bolt, or dowel can be used to secure the display system to sidewall 12. When fastened to an airplane sidewall, which can include a structural service panel exterior an upholstery panel, a fastener can be used to secure the mounting plate to the service panel. In some embodiments, such a fastener can pass through an aperture in the curvature accommodating device. For example, as shown in FIGS. 2 and 3, the curvature accommodating devices can include apertures 52, through which a fastener can pass. In the illustrated embodiment, the apertures are oval shaped to allow a fastener to pass through regardless of the amount the bar is pivoted away from the mounting plate. In some embodiments, mated mounting brackets can be used to fasten the display system to a sidewall. The display system can include a shroud designed to improve the aesthetics of an installed display system.

As shown in FIG. 1, arm 20 can be configured to move in a plane that is at an oblique angle relative to the frame assembly. In particular, the arm may be at an angle φ relative to the frame assembly. In some embodiments, φ may be set at approximately 70 degrees. The frame assembly can be mounted to the sidewall so that the arm remains substantially horizontal throughout its entire range of motion. In other words, the plane through which arm 20 moves can be set by positioning the frame assembly with a given orientation, and the orientation can be selected to maintain a level arm, which in turn can maintain a level video display. To maintain a level video display, the frame assembly can be positioned at an angle α relative to a viewers vertical reference, where α=(90−φ).

An angle α can be achieved by setting the relative spacing of the curvature accommodating device(s). For example, with reference to FIG. 1, α can be increased by pivoting curvature accommodating bar 42 farther away from the mounting plate and/or pivoting curvature accommodating bar 46 closer to the mounting plate. Likewise, a can be decreased by pivoting curvature accommodating bar 42 closer to the mounting plate and/or pivoting curvature accommodating bar 46 farther away from the mounting plate. Such adjustments can permit the display system to be precisely mounted despite minor differences and/or irregularities in the sidewall to which the display system is being mounted.

As discussed above, a video display can be orientated with the screen facing inward or outward when in a stowed position. The video display can pivot about axis B-B, thus setting the orientation of the screen. FIG. 6 shows a front 14a of the video display facing outward, while FIG. 7 shows a back 14b of the video display facing outward. A video display may be orientated with the screen facing outward when the screen is used in the stowed position. Likewise, the video display may be orientated with the screen facing inward when added protection is desired.

In some embodiments, arm 20 can be selectively connected to either the left side of frame assembly 18 or the right side of frame assembly 18. FIG. 6 shows arm 20 connected to the right side of frame assembly 18. A latch assembly 60 is connected to the left side of the frame assembly. Latch assembly 60 can be used to selectively secure the video display in a stowed position. In FIG. 7, arm 20 and latch 60 have been exchanged so that arm 20 pivots from the left side of the frame assembly. This effectively allows axis A-A to be set on either the left or right side of a display system.

The ability to adapt a single display system so that arm 20 can swing from either the left side or the right side of the frame assembly increases mounting options. A single display system can be mounted on a left sidewall with arm 20 pivotably connected to the left side of frame assembly 18 or with arm 20 pivotably connected to the right side of frame assembly 18. Likewise, a single display system can be mounted on a right sidewall with arm 20 pivotably connected to the left side of frame assembly 18 or with arm 20 pivotably connected to the right side of frame assembly 18.

While described with reference to the embodiment illustrated in FIGS. 1-7, it should be understood that a display system can be differently configured while remaining within the scope of this disclosure. For example, in some embodiments, a display system may have only two axes of rotation, while in other embodiments, a display system may have four or more axes of rotation. Similarly, it should be understood that curvature accommodating bar 46 and set screw 50 are provided as a nonlimiting example of a curvature accommodating device. In some embodiments, two or more discrete curvature accommodating devices can be used in place of a single bar. Such devices can optionally be horizontally aligned and individually adjustable. Such an arrangement may provide an improved fit if a sidewall not only curves from top to bottom, but also from front to back. In some embodiments, a spring or other resilient member can be used to span at least a portion of the distance from the mounting plate to the sidewall. Similarly, a mechanism other than a set screw can be used to adjust the curvature accommodating device.

Although the present disclosure has been provided with reference to the foregoing operational principles and embodiments, it will be apparent to those skilled in the art that various changes in form and detail may be made without departing from the spirit and scope defined in the appended claims. The present disclosure is intended to embrace all such alternatives, modifications and variances. Where the disclosure or claims recite “a,” “a first,” or “another” element, or the equivalent thereof, they should be interpreted to include one or more such elements, neither requiring nor excluding two or more such elements.

1. A display system, comprising:
a frame assembly including a mounting plate;
a video display moveably connected to the frame assembly, wherein the video display is selectively moveable throughout a range of positions;
at least a first curvature accommodating bar extending laterally along a backside of the mounting plate, wherein the first curvature accommodating bar is pivotably connected to the mounting plate; and
a first adjustable spacer configured to set the relative degree of pivot between the first curvature accommodating bar and the mounting plate.

2. The display system of claim 1, further comprising a second curvature accommodating bar extending laterally along the backside of the mounting plate, wherein the second curvature accommodating bar is pivotably connected to the mounting plate, and a second adjustable spacer configured to set the relative degree of pivot between the second curvature accommodating bar and the mounting plate.

3. The display system of claim 1, wherein the first curvature accommodating bar laterally extends at least substantially an entire distance across the backside of the mounting plate.

4. The display system of claim 1, wherein the first curvature accommodating bar laterally extends a partial distance along the backside of the mounting plate.

5. The display system of claim 1, wherein the first curvature accommodating bar includes an aperture configured to permit passage of a fastener connecting the mounting plate to a sidewall.

6. A display system, comprising:
a frame assembly;
an arm having a first end and a second end, wherein the first end is pivotably connected to the frame assembly for rotation about a first axis that is oblique relative to the frame assembly; and
a video display assembly connected to the second end of the arm.

7. The display system of claim 6, wherein the first axis is substantially vertical relative to a viewer's reference.

8. The display system of claim 6, wherein the video display assembly is pivotably connected to the second end of the arm for rotation about a second axis substantially parallel to the first axis.

9. The display system of claim 8, wherein the video display assembly is pivotably connected to the second end of the arm for rotation about a third axis substantially perpendicular to the first and second axes.

10. The display system of claim 8, wherein the video display assembly is pivotably connected to the second end of the arm for at least 180 degrees of rotation about the second axis.

11. The display system of claim 6, wherein the video display assembly is pivotably connected to the second end of the arm for rotation about a third axis substantially perpendicular to the first axis.

12. The display system of claim 11, wherein the third axis is substantially horizontal relative to a viewer's reference.

13. The display system of claim 6, wherein the frame assembly is configured to mount to an inwardly curving sidewall.

14. The display system of claim 6, wherein the frame assembly includes at least one adjustable curvature accommodating device.

15. The display system of claim 14, wherein the adjustable curvature accommodating device includes a bar laterally extending along a backside of the frame assembly, wherein the bar is pivotably connected to the frame assembly, and wherein the curvature accommodating device further includes an adjustable spacer configured to set the relative degree of pivot between the bar and the frame assembly.

16. The display system of claim 6, wherein the arm is configured to selectively hold the video display assembly in a stowed position, pivot in a substantially horizontal plane about the first axis, and hold the video display assembly in a deployed position.

17. The display system of claim 6, wherein the video display assembly selectively faces the frame assembly or faces away from the frame assembly in a stowed position.

18. The display system of claim 6, wherein the arm is configured for selective connection to either a left side or a right side of the frame assembly.

19. A display system, comprising:
a frame assembly;
a video display; and
a positioning assembly configured to selectively move the video display between a deployed position and a stowed position, wherein the positioning assembly is configured to selectively hold the video display in the stowed position with the video display facing the frame assembly or in the stowed position with the video display facing away from the frame assembly.

20. The display system of claim 19, wherein the positioning assembly is configured for selective connection to either a left side or a right side of the frame assembly.

21. A display system, comprising:
a frame assembly;
a video display assembly moveably connected to the frame assembly, wherein the video display assembly includes a screen selectively moveable throughout a range of positions; and
an adjustable mounting assembly configured to fit the frame assembly to an inwardly curving sidewall at a desired orientation.

22. The display system of claim 21, wherein the desired orientation keeps the screen substantially level throughout the range of positions.

23. A display system, comprising:
a frame assembly including a mounting plate having a front side and a backside;
a first curvature accommodating bar extending laterally across a top half of the backside of the mounting plate, wherein the first curvature accommodating bar is pivotably connected to the mounting plate;
a first adjustable spacer configured to set the relative degree of pivot between the first curvature accommodating bar and the mounting plate;
a second curvature accommodating bar extending laterally across a bottom half of the backside of the mounting plate, wherein the second curvature accommodating bar is pivotably connected to the mounting plate;
a second adjustable spacer configured to set the relative degree of pivot between the second curvature accommodating bar and the mounting plate;
an arm having a first end and a second end, wherein the first end is pivotably connected to the frame assembly for rotation about a first axis that is oblique relative to the mounting plate; and
a video display assembly pivotably connected to the second end of the arm for rotation about a second axis substantially parallel to the first axis and a third axis substantially perpendicular to the first and second axes, wherein in a stowed position the video display selectively faces the front side of the mounting plate or faces away from the front side of the mounting plate.

24. The display system of claim 23, wherein the arm is configured for selective connection to either a left side or a right side of the frame assembly.
